(19) United States
(12) Patent Application Publication
(10) Pub. No.: US 2023/0169226 A1
(43) Pub. Date: Jun. 1, 2023

(54) METHOD AND SYSTEM FOR INTERFACING A TESTBENCH TO CIRCUIT SIMULATION

(71) Applicant: Xilinx, Inc., San Jose, CA (US)

(72) Inventors: Saikat Bandyopadhyay, San Jose, CA (US); Shiyao Ge, San Jose, CA (US)

(73) Assignee: Xilinx, Inc., San Jose, CA (US)

(21) Appl. No.: 17/538,497

(22) Filed: Nov. 30, 2021

(51) Int. Cl. G06F 30/20; G06F 30/333; G01R 31/3183

(52) U.S. Cl. CPC G06F 30/20; G06F 30/333; G01R 31/318357

(57) ABSTRACT

Approaches for simulating a circuit include receiving simulation input data from a testbench executing on a computer system by a simulator interface executing on the computer system. The simulator interface receives simulation output data the according to a hardware bus protocol specified by a simulated circuit for communication and simulates handshaking with the simulated circuit according to the hardware bus protocol in response to receiving the simulation input data and simulation output data. The simulator interface provides the simulation input data to the simulated circuit by according to the hardware bus protocol and provides the simulation output data to the testbench.

### TECHNICAL FIELD

The disclosure generally relates to simulating digital circuits.

### BACKGROUND

Simulation is an important part of the design flow for implementing a digital circuit from a circuit design. Simulating operation of a circuit based on the circuit design is critical to verify the function of the circuit as well as performance. Satisfactory simulation of a circuit involves a testbench that provides simulation input data and receives and evaluates simulation output data. In many instances, the testbench is a computer system configured to execute software that has been compiled from a high-level language such as C++.

A significant portion of the designer's time devoted to simulation involves developing the testbench, with certain features of the circuit design adding to the complexity of the testbench. For example, some digital circuit designs specify a bus protocol, such as AXI4-stream, for communicating between various modules of the design. AXI4-stream is a popular protocol for high-speed communication of streaming data. AXI is the acronym of Advanced eXtensible Interface.

Though the bus is part of the circuit design, testing operation of the bus may be unnecessary as the bus logic may be a module that has previously been verified. Requiring the designer to develop a testbench that includes code that operates according to the bus protocol can add to the time required to develop the testbench.

### SUMMARY

A disclosed method includes receiving simulation input data from a testbench executing on a computer system by a simulator interface executing on the computer system, and receiving simulation output data by the simulator interface according to a hardware bus protocol specified by a simulated circuit for communication. The method further includes simulating by the simulator interface, handshaking with the simulated circuit according to the hardware bus protocol in response to receiving the simulation input data and simulation output data, and providing the simulation input data to the simulated circuit by the simulator interface according to the hardware bus protocol. The method includes providing the simulation output data to the testbench by the simulator interface.

A disclosed system includes one or more computer processors configured to execute program code and a memory arrangement coupled to the one or more computer processors. The memory arrangement is configured with instructions that when executed by the one or more computer processors cause the one or more computer processors to perform operations including receiving simulation input data from a testbench by a simulator interface and receiving simulation output data by the simulator interface according to a hardware bus protocol specified by a simulated circuit for communication. The instructions further cause the one or more computer processors to simulate by the simulator interface, handshaking with the simulated circuit according to the hardware bus protocol in response to receiving the simulation input data and simulation output data, provide the simulation input data to the simulated circuit by the simulator interface according to the hardware bus protocol, and provide the simulation output data to the testbench by the simulator interface.

Other features will be recognized from consideration of the Detailed Description and Claims, which follow.

### BRIEF DESCRIPTION OF THE DRAWINGS

Various aspects and features of the methods and systems will become apparent upon review of the following detailed description and upon reference to the drawings in which:

FIG. 1 shows a flow diagram for creating a circuit simulation and a testbench that communicates with the circuit simulation via a language-standard input stream and output stream and a simulator interface that handles bus protocol interactions with the circuit simulation;

FIG. 2 shows a flowchart of a testbench process for providing input data to and receiving output data from a circuit simulation via output and input streams with a simulator interface;

FIG. 3 shows a flowchart of a simulator interface process for simulating clock signals to the bus of the circuit simulation;

FIG. 4 shows a flowchart of a simulator interface process for receiving data from the output stream of the testbench;

FIG. 5 shows a flowchart of a simulator interface process for providing data received from the testbench and buffered, to the circuit simulation according to the bus protocol;

FIG. 6 shows a flowchart of a simulator interface process for providing data received from the circuit simulation and buffered, to the input stream of the testbench;

FIG. 7 shows a flowchart of a simulator interface process for receiving circuit simulation output data according to the bus protocol;

FIG. 8 shows the input stream and output stream data flow between the testbench and simulator interface, and the data flow and bus protocol controls between the simulator interface and a bus master and a bus slave of a circuit simulation; and

FIG. 9 is a block diagram illustrating an exemplary data processing system.

### DETAILED DESCRIPTION

In the following description, numerous specific details are set forth to describe specific examples presented herein. It should be apparent, however, to one skilled in the art, that one or more other examples and/or variations of these examples may be practiced without all the specific details given below. In other instances, well known features have not been described in detail so as not to obscure the description of the examples herein. For ease of illustration, the same reference numerals may be used in different diagrams to refer to the same elements or additional instances of the same element.

Known APIs available for developing a testbench include functions that can be initiated to provide low-level control over various pins of a bus interface. For example, functions are provided for selecting individual input/output pins, asserting signal values on input pins, reading signal values from output pins, running the circuit simulation for a specified number of clock cycles, and controlling durations of high and low states of a clock signal.

A bus protocol can include handshaking between master and slave components for coordinating communications via the bus, and the APIs enable testbench participation in the handshaking. However, requiring the testbench to participate in handshaking and other required controls at the pin level may lead to errors in the testbench.

According to the disclosed methods and systems, high-level programming language objects/interfaces can be used in a testbench to interface with a circuit simulation. A circuit design along with a simulator interface can be compiled into a dynamically linked library (DLL). The testbench, which is linked to the DLL, can be configured with language-standard istream and ostream objects that are associated with bus ports of the circuit design, and the simulator interface is configured to interface with the bus ports according to a bus protocol.

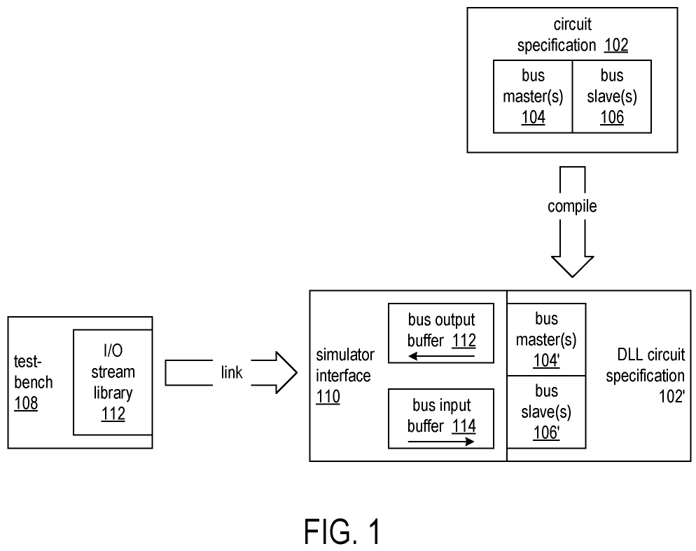

FIG. 1 shows a flow diagram for creating a circuit simulation and a testbench that communicates with the circuit simulation via a language-standard input stream and output stream and a simulator interface that handles bus protocol interactions with the circuit simulation. A circuit to be simulated can be specified in a hardware description language (HDL) such as Verilog, VHDL, or System C, as shown by circuit specification 102. The circuit specification can include one or more bus masters 104 and one or more bus slaves 106. The bus protocol implemented by the bus masters and bus slaves involves unidirectional data flow(s) from bus master(s) to bus slave(s). For example, the bus master(s) and bus slave(s) can implement AXI4-streams.

The circuit specification 102 can be compiled into a DLL that includes the DLL circuit specification 102′ and functions of a simulator interface 110. Instead of compiling the circuit specification 102 into executable code, the DLL provides a lightweight approach to drive the circuit simulation from a high-level language (e.g., C or C++) testbench 108.

The simulator interface 110 provides application program interfaces (APIs) that can be used by the testbench to obtain handles of ports of the circuit specification, as compiled into the DLL circuit specification 102′. The APIs also enable the testbench to set/write values for input to and read values output from the circuit simulation, via the port handles. The testbench can also control input of simulated clock signals to the circuit simulation via the APIs.

The APIs provided by the simulator interface enable the testbench 108 to use language-standard stream input and stream output functions to input data to bus slave(s) 106′ and receive output data from bus masters 104′ of the circuit simulation. For example, C++ has a standard input stream class (“istream”) and a standard output stream class (“ostream”). A C++ program can instantiate an istream object for inputting some number of bytes and an ostream object for outputting some number bytes. The I/O stream library 112 can define classes that inherit from the language-standard istream and ostream classes, and the testbench can instantiate objects for streaming data to and from the circuit simulation via those objects, which are linked to functions of the simulator interface.

The simulator interface uses bus output buffer 112 to temporarily store data output by the bus master(s) 104′ until the data is read by via the testbench istream. The bus input buffer is 114 is used by the simulator interface to temporarily store data provided by the testbench ostream for input to the bus slave(s) 106′.

In addition to handling the language-standard streaming input/output between the testbench 108 and the DLL circuit specification 102′, the simulator interface handles bus protocol-specific interactions with the bus master(s) 104′ and bus slave(s) 106′ on behalf of the testbench. For example, the simulator interfaces simulates handshake signals of the bus protocol on behalf of the testbench. For instances in which the testbench is configured to receive output data from a bus master 104′ and instances in which the testbench is configured to provide input data to a bus slave 106′, the simulator interface handles simulation of the handshake signals with the bus master and bus slave while handling the language-standard streams with the testbench.

The code of Example 1 below shows exemplary functions of a testbench according to the disclosed approaches.

```
Xsi::Loader dut(design_name);
Xsi::Clock ck(5);
try {
  Xsi::axi_ostream &axis_A =
            dut.get_axi_slave_port(“A”,ck);
  Xsi::axi_istream &axis_O =
            dut.get_axi_master_port(“O”,ck);
  ...
  axis_A << value;
  dut.async_run(100); //start the simulation and return
  ...
  axis_O >> result;
  ...
} catch (Xsi::LoaderException &err) {
      std::cerr << “Error: @” << err.when( ) << ”: “<<
        err.what( ) << std::eol;
}
```

### Example 1

If the get_axi_< >_port( ) function fails, for example, if the design does not have the expected AXI ports/interface, the catch section is executed instead of continuing with the rest of the simulation; input to axi port A is not sent via axis_A>>value.

In the code of Example 1, axis_A is an ostream-type object for the data input port of a bus slave “A,” and axis_O is an istream-type object for the data output port of a bus master “0.” The testbench assigns value to the ostream object axis_A via the stream operator “<<” and then calls on the simulator interface to run the clock for 100 cycles, after which control is returned to the testbench.

The simulated clock signals are asynchronous in that separate threads execute the testbench and the circuit simulation, and control is returned to the testbench immediately. Upon return, the testbench can poll on the output stream for result data. Operating the circuit simulation and the testbench concurrently provides efficient throughput of large quantities of test data. The circuit simulation suspends execution in response to expiration of the specified time or completion of the simulation.

The testbench reads from the istream object axis_O and assigns the data to the variable result via the stream operator “>>.”

The code of Example 2 shows an exemplary interface of Xsi::axi_ostream.

```
namespace xsi {
  class axi_ostream : public std::ostream {
  public:
    axi_ostream& put(char c);
    axi_ostream& write(const char* s, streamsize n);
    axi_ostream& flush( );
    streampos tellp( );
    axi_ostream& seekp(streampos& pos);
    axi_ostream& operator<<( );
  };
}
```

### Example 2

The code of Example 3 shows an exemplary interface of Xsi::axi_istream.

```
namespace xsi {
  class axi_istream : public std::istream {
  public:
    streamsize gcount( ) const;
    axi_istream& get( );
    axi_istream& getline(char* s, streamsize n);
    char peek( );
    axi_istream& read(const char* s, streamsize n);
    streamsize readsome(char* s, streamsize n);
    streampos tellp( );
    axi_istream& seekp(streampos& pos);
    axi_istream& operator>>( );
  };
}
```

### Example 3

The I/O stream library 112 includes a class, “Xsi::Clock,” that can be used in the testbench to define a clock attached to ACLK port of bus master(s) 104′ and bus slave(s) 106′. The exemplary code of Example 4 shows the API provided by the

```
Clock class of Xsi.
namespace Xsi {
class Clock {
  public:
    Clock(int halfPeriod);
    Clock(int onTime, int offTime);
    drive(int portNumber);
  };
}
```

### Example 4

The Clock class allows the clock signal to be simulated according to two alternative approaches. According to one approach, halfPeriod can be specified to drive the clock ports alternatively to high and low states every halfPeriod time. The second approach allows the clock signal to be driven asymmetrically. In simulating an asymmetric clock signal, the signal will be in a high state onTime, followed by a low state for offTime. The object can be reused to drive several ports by registering portNumber by the drive ( ) member function.

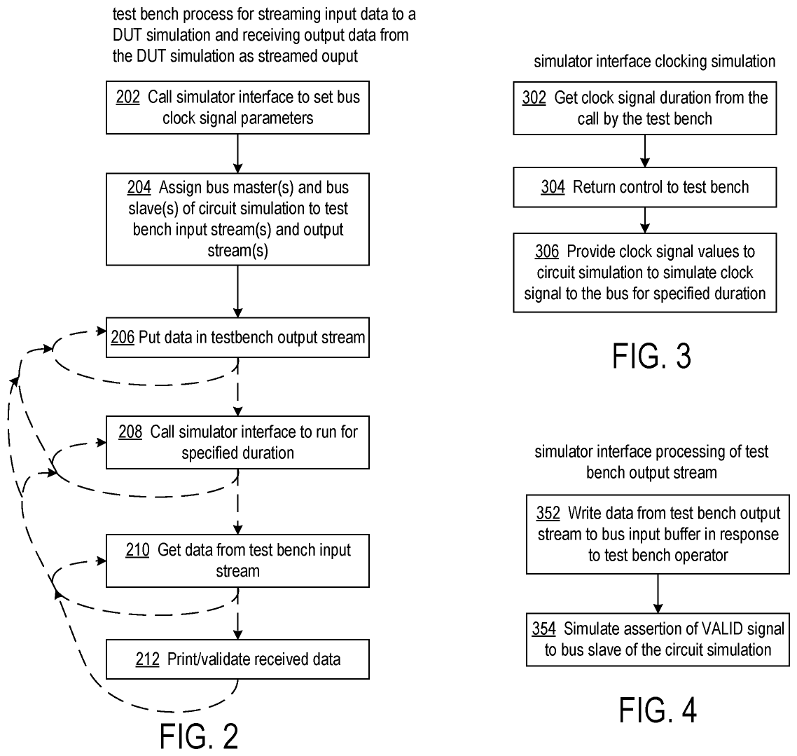

FIG. 2 shows a flowchart of a testbench process for providing input data to and receiving output data from a circuit simulation via output and input streams with a simulator interface. At block 202, the testbench calls the simulator interface to set the parameters of the bus clock signal. For example, the testbench can set the halfperiod to 5 nanoseconds as in Example 1 above. At block 204, the testbench assigns named ports of the bus master(s) and bus slave(s) to istream and ostream objects of the testbench.

It will be recognized that the sequence and repetition of blocks 206, 208, 210, and 212 can vary according to test requirements and logic flow of the simulated circuit. The dashed lines signify examples of possible testbench flows. At block 206, the testbench puts data in the ostream object.

At block 208, the testbench calls the function of the simulator interface to simulate input of a clock signal to the circuit simulation for a specified duration, such as a number of clock cycles or real time. The testbench and circuit simulation can be executed by separate threads, and control is returned to the testbench immediately. Upon return, the testbench can poll on the output stream for result data.

At block 210, the testbench reads data from the istream object, and at block 212 the testbench can evaluate and print result data.

FIG. 3 shows a flowchart of a simulator interface process for simulating clock signals to the bus of the circuit simulation. At block 302, the simulator interface obtains the duration for which the clock signal is to be cycled to the simulated circuit in response to the function call by the testbench. The simulator interface immediately returns control to the testbench at block 304, and at block 306 inputs a simulated clock signal to the circuit simulation for the specified duration.

FIG. 4 shows a flowchart of a simulator interface process for receiving data from the output stream of the testbench. At block 352, the simulator interface responds to the testbench putting data in the testbench ostream object by writing data to the bus input buffer of the simulator interface. At block 354, the simulator interface simulates part of the handshake protocol with the bus slave associated with the ostream by simulating assertion of a VALID signal to the bus slave. The asserted VALID signal indicates to the bus slave that there is data available on the data port.

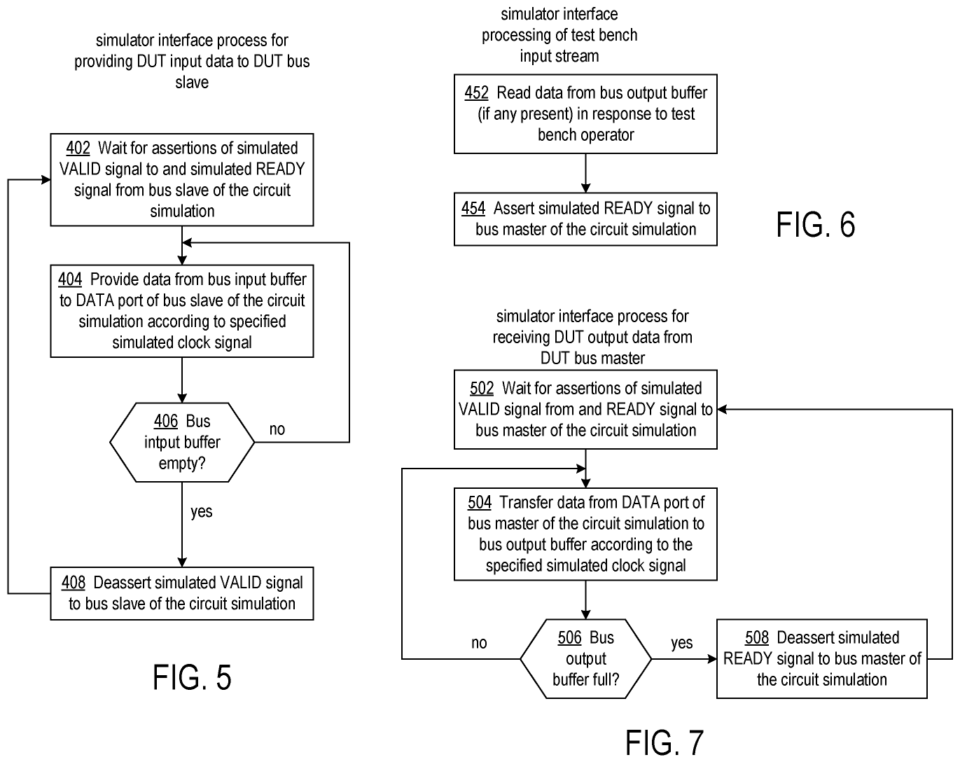

FIG. 5 shows a flowchart of a simulator interface process for providing data received from the testbench and buffered, to the circuit simulation according to the bus protocol. At block 402, the simulator interface waits for simulated VALID signal to the bus slave and a simulated handshake READY signal from the bus slave to be asserted. In response to both the VALID and READY signals being asserted, at block 404 the simulator interface provides data from the bus input buffer to the associated DATA port of the bus slave consistent with the specified duration of the simulated clock signal.

At decision block 406 and in response to the bus input buffer being empty, the simulator interface deasserts the simulated VALID signal to the bus slave at block 408 and returns to block 402 to await assertions of the VALID and READY signals. Otherwise, the simulator interface continues providing data from the bus input buffer to the bus slave at block 404.

FIG. 6 shows a flowchart of a simulator interface process for providing data received from the circuit simulation and buffered, to the input stream of the testbench. At block 452, in response to execution in the testbench of the “<<” istream operator, the simulator interface reads data from the bus output buffer and provides the data, if any is present, for storing in the variable/object specified by the testbench. At block 454, the simulator interface asserts the simulated READY signal of the protocol to the bus master of the circuit simulation that data can be output.

FIG. 7 shows a flowchart of a simulator interface process for receiving circuit simulation output data according to the bus protocol. At block 502, the simulator interface waits for assertions of the simulated VALID and READY signals of the handshake protocol. The bus master of the circuit simulation asserts the VALID signal. At block 504, the simulator interface transfers data from the DATA port of the simulated bus master to the bus output buffer of the simulator interface, consistent with the duration of the simulated clock signal.

In response to the bus output buffer being full, at decision block 506 the simulator interface deasserts the simulated READY signal to the bus master and returns to block 502 to wait for the VALID and READY signals to be asserted. Otherwise, the simulator interface returns to block 508 and continues transferring data output by the bus master to the bus output buffer.

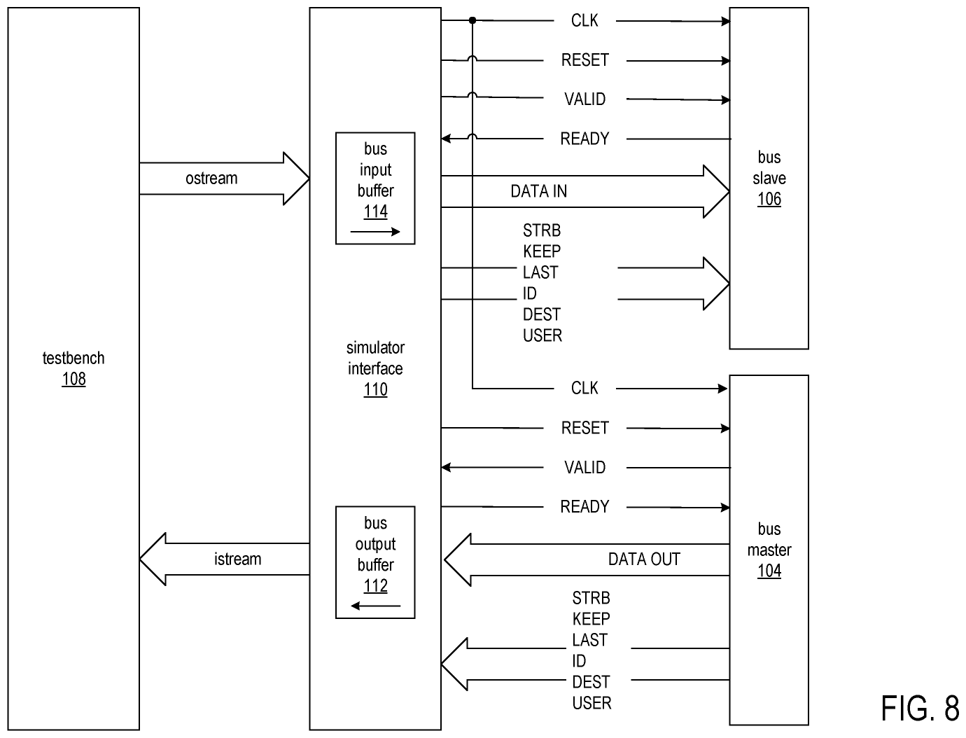

FIG. 8 shows the input stream and output stream data flow between the testbench 108 and simulator interface 110, and the data flow and bus protocol controls between the simulator interface and a bus master 104 and a bus slave 104 of a circuit simulation.

A simulated AXI4-stream bus master 104 specifies the following ports for use in simulation: CLK, RESET, READY and DATA with any valid size. The VALID port can be optional for the bus master, and the simulator interface handles the KEEP port, if present by removing NULL data from the bus output data. For the following ports the simulator interface ignores output values or checks for permitted values. For STRB, the simulator can check whether or not all bits are all logic 1; output on the LAST can be ignored; output on the ID port can be checked for all logic 0 bits or ignored; output on the DEST port can be checked for all logic 0 bits or ignored; and output on the USER port can be checked for all logic 0 bits or ignored.

A simulated AXI4-stream bus slave 106 specifies the following ports for use in simulation: CLK, RESET, VALID and DATA with any valid size. The READY port can be optional for the bus slave, and the simulator interface handles the KEEP port if present. If the KEEP port is absent, data streamed from the testbench is expected to be a multiple of the bit-width of the DATA port.

For the STRB port, the simulator sends all logic 1 bits; for the ID port, the simulator interface sends all logic 0 bits; for the DEST port, the simulator interface sends all logic 0 bits; and for the USER port, the simulator interface sends all logic 0 bits.

For the LAST port, the simulator interface sends a logic 1 bit if the testbench calls the ostream::flush( ) function, 0 otherwise. For processing efficiency, C++ istreams and ostreams can temporarily store data in a buffer without sending. The flush( ) function forces buffered data in the simulated hardware pipe to be sent via asserting LAST. Similarly with the AXI4-stream protocol, the state of the LAST signal indicates the end of data for a packet in order to flush any buffered data of the packet.

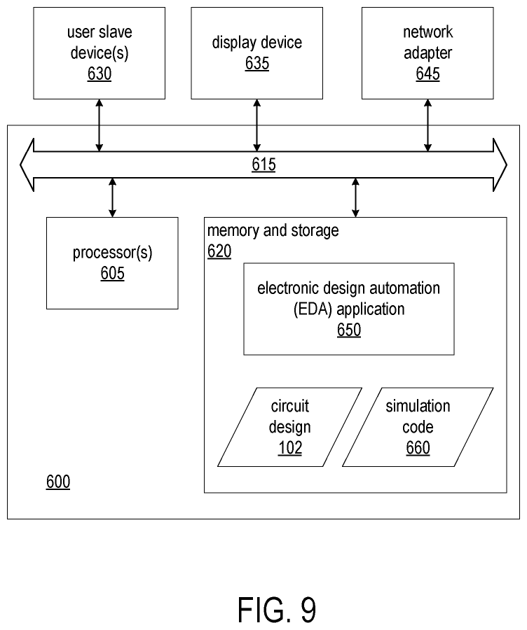

FIG. 9 is a block diagram illustrating an exemplary data processing system (system) 600. System 600 is an example of an EDA system. As pictured, system 600 includes at least one processor circuit (or “processor”), e.g., a central processing unit (CPU) 605 coupled to memory and storage arrangement 620 through a system bus 615 or other suitable circuitry. System 600 stores program code and circuit specification 102 within memory and storage arrangement 620. Processor 605 executes the program code accessed from the memory and storage arrangement 620 via system bus 615. In one aspect, system 600 is implemented as a computer or other data processing system that is suitable for storing and/or executing program code. It should be appreciated, however, that system 600 can be implemented in the form of any system including a processor and memory that is capable of performing the functions described within this disclosure.

Memory and storage arrangement 620 includes one or more physical memory devices such as, for example, a local memory (not shown) and a persistent storage device (not shown). Local memory refers to random access memory or other non-persistent memory device(s) generally used during actual execution of the program code. Persistent storage can be implemented as a hard disk drive (HDD), a solid state drive (SSD), or other persistent data storage device. System 600 may also include one or more cache memories (not shown) that provide temporary storage of at least some program code and data in order to reduce the number of times program code and data must be retrieved from local memory and persistent storage during execution.

Input/output (I/O) devices such as user input device(s) 630 and a display device 635 may be optionally coupled to system 600. The I/O devices may be coupled to system 600 either directly or through intervening I/O controllers. A network adapter 645 also can be coupled to system 600 in order to couple system 600 to other systems, computer systems, remote printers, and/or remote storage devices through intervening private or public networks. Modems, cable modems, Ethernet cards, and wireless transceivers are examples of different types of network adapter 645 that can be used with system 600.

Memory and storage arrangement 620 may store an EDA application 650. EDA application 650, being implemented in the form of executable program code, is executed by processor(s) 605. As such, EDA application 650 is considered part of system 600. System 600, while executing EDA application 650, receives and operates on circuit specification 102. In one aspect, system 600 performs a design flow on circuit specification 102, and the design flow may include synthesis, mapping, placement, routing, and generation of data for implementing the circuit on an integrated circuit device. In addition, the EDA can compile the circuit specification 102 into a DLL circuit specification linked with a testbench as simulation code 660.

EDA application 650, circuit specification 102, simulation code 660, and any data items used, generated, and/or operated upon by EDA application 650 are functional data structures that impart functionality when employed as part of system 600 or when such elements, including derivations and/or modifications thereof, are loaded into an IC such as a programmable IC causing implementation and/or configuration of a circuit design within the programmable IC.

Various logic may be implemented as circuitry to carry out one or more of the operations and activities described herein and/or shown in the figures. In these contexts, a circuit or circuitry may be referred to as “logic,” “module,” “engine,” or “block.” It should be understood that logic, modules, engines and blocks are all circuits that carry out one or more of the operations/activities. In certain implementations, a programmable circuit is one or more computer circuits programmed to execute a set (or sets) of instructions stored in a ROM or RAM and/or operate according to configuration data stored in a configuration memory.

Though aspects and features may in some cases be described in individual figures, it will be appreciated that features from one figure can be combined with features of another figure even though the combination is not explicitly shown or explicitly described as a combination.

The methods and systems are thought to be applicable to a variety of systems for simulating circuits. Other aspects and features will be apparent to those skilled in the art from consideration of the specification. The methods and systems may be implemented as one or more processors configured to execute software, as an application specific integrated circuit (ASIC), or as a logic on a programmable logic device. It is intended that the specification and drawings be considered as examples only, with a true scope of the invention being indicated by the following claims.

What is claimed is:

1. A method comprising:
receiving simulation input data from a testbench executing on a computer system by a simulator interface executing on the computer system;
receiving simulation output data by the simulator interface according to a hardware bus protocol specified by a simulated circuit for communication;
simulating by the simulator interface, handshaking with the simulated circuit according to the hardware bus protocol in response to receiving the simulation input data and simulation output data;
providing the simulation input data to the simulated circuit by the simulator interface according to the hardware bus protocol; and
providing the simulation output data to the testbench by the simulator interface.

2. The method of claim 1, wherein receiving the simulation input data includes receiving the simulation input data via a software standard output stream implemented by the testbench.

3. The method of claim 1, wherein providing the simulation output data includes providing the simulation output data via a software standard input stream implemented by the testbench.

4. The method of claim 1, further comprising:
simulating generation of a clock signal to the simulation of the simulated circuit by the simulator interface in response to a specification of the clock signal by the testbench.

5. The method of claim 4, wherein simulating generation of the clock signal includes driving a clock port of the simulation of the simulated circuit with values that alternate every half period in response to the specification of the clock signal specifying a value of the half period.

6. The method of claim 4, wherein simulating generation of the clock signal includes driving a clock port of the simulation of the simulated circuit with values that alternate in response to the specification of the clock signal specifying a first duration of one of the alternating values and a second duration of another of the alternating values.

7. The method of claim 1, further comprising:
executing the simulation of the simulated circuit by a first thread;
executing the testbench by a second thread;
wherein providing the simulation output data includes providing the simulation output data via a software standard input stream implemented by the testbench; and
polling the software standard input stream by the second thread.

8. The method of claim 1, wherein:
receiving the simulation input data includes:
receiving the simulation input data via a software standard output stream implemented by the testbench, and
storing the simulation input data in an input buffer; and
providing the simulation input data to the simulated circuit includes:
reading the simulation input data from the input buffer, and
providing the simulation input data to a data port of the simulated circuit.

9. The method of claim 1, wherein:
receiving simulation output data includes transferring the simulation output data from a data port of the simulated circuit to an output buffer; and
providing the simulation output data includes:
reading the simulation output data from the output buffer, and
providing the simulation output data to the testbench via a software standard input stream implemented by the testbench.

10. The method of claim 1, wherein:
receiving the simulation input data includes receiving the simulation input data via a software standard output stream implemented by the testbench, and asserting a first VALID handshake signal to the simulated circuit by the simulator interface;
providing the simulation input data includes waiting for assertion of the first VALID handshake signal and assertion of a first READY signal from the simulated circuit before providing the simulation input data;
providing the simulation output data includes providing the simulation output data via a software standard input stream implemented by the testbench and asserting a second READY signal to the simulated circuit by the simulator interface; and
receiving simulation output data includes waiting for assertion of the second READY signal and assertion of a second VALID signal from the before receiving the simulation output data.

11. A system comprising:
one or more computer processors configured to execute program code; and
a memory arrangement coupled to the one or more computer processors, wherein the memory arrangement is configured with instructions that when executed by the one or more computer processors cause the one or more computer processors to perform operations including:
receiving simulation input data from a testbench by a simulator interface;
receiving simulation output data by the simulator interface according to a hardware bus protocol specified by a simulated circuit for communication;
simulating by the simulator interface, handshaking with the simulated circuit according to the hardware bus protocol in response to receiving the simulation input data and simulation output data;
providing the simulation input data to the simulated circuit by the simulator interface according to the hardware bus protocol; and
providing the simulation output data to the testbench by the simulator interface.

12. The system of claim 11, wherein the instructions for receiving the simulation input data include instructions for receiving the simulation input data via a software standard output stream implemented by the testbench.

13. The system of claim 11, wherein the instructions for providing the simulation output data include instructions for providing the simulation output data via a software standard input stream implemented by the testbench.

14. The system of claim 11, the memory arrangement is further configured with instructions that when executed by the one or more computer processors cause the one or more computer processors to perform operations including:
simulating generation of a clock signal to the simulation of the simulated circuit by the simulator interface in response to a specification of the clock signal by the testbench.

15. The system of claim 14, wherein the instructions for simulating generation of the clock signal include instructions for driving a clock port of the simulation of the simulated circuit with values that alternate every half period in response to the specification of the clock signal specifying a value of the half period.

16. The system of claim 14, wherein the instructions for simulating generation of the clock signal include instructions for driving a clock port of the simulation of the simulated circuit with values that alternate in response to the specification of the clock signal specifying a first duration of one of the alternating values and a second duration of another of the alternating values.

17. The system of claim 11, wherein the memory arrangement is further configured with instructions that when executed by the one or more computer processors cause the one or more computer processors to perform operations including:
executing the simulation of the simulated circuit by a first thread;
executing the testbench by a second thread;
wherein the instructions for providing the simulation output data include instructions for providing the simulation output data via a software standard input stream implemented by the testbench; and
polling the software standard input stream by the second thread.

18. The system of claim 11, wherein:
the instructions for receiving the simulation input data include instructions for:
receiving the simulation input data via a software standard output stream implemented by the testbench, and
storing the simulation input data in an input buffer; and
providing the simulation input data to the simulated circuit includes:
reading the simulation input data from the input buffer, and
providing the simulation input data to a data port of the simulated circuit.

19. The system of claim 11, wherein:
the instructions for receiving simulation output data include instructions for transferring the simulation output data from a data port of the simulated circuit to an output buffer; and
the instructions for providing the simulation output data include instructions for:
reading the simulation output data from the output buffer, and
providing the simulation output data to the testbench via a software standard input stream implemented by the testbench.

20. The system of claim 11, wherein:
the instructions for receiving the simulation input data include instructions for receiving the simulation input data via a software standard output stream implemented by the testbench, and asserting a first VALID handshake signal to the simulated circuit by the simulator interface;
the instructions for providing the simulation input data include instructions for waiting for assertion of the first VALID handshake signal and assertion of a first READY signal from the simulated circuit before providing the simulation input data;
the instructions for providing the simulation output data include instructions for providing the simulation output data via a software standard input stream implemented by the testbench and asserting a second READY signal to the simulated circuit by the simulator interface; and
the instructions for receiving simulation output data include instructions for waiting for assertion of the second READY signal and assertion of a second VALID signal from the before receiving the simulation output data.
